(19) United States
(12) Patent Application Publication
(10) Pub. No.: US 2021/0351292 A1
(43) Pub. Date: Nov. 11, 2021

(54) METAL OXIDE SEMICONDUCTOR FIELD EFFECT TRANSISTOR AND METHOD FOR MANUFACTURING THE SAME

(71) Applicant: Cystech Electronics Corp., New Taipei City (TW)

(72) Inventors: HSIN-YU HSU, New Taipei City (TW); YUNG-CHANG CHEN, New Taipei City (TW); Chen-Huang Wang, New Taipei City (TW)

(21) Appl. No.: 16/866,768

(22) Filed: May 5, 2020

(51) Int. Cl. H01L 29/78; H01L 29/06; H01L 29/10; H01L 29/423; H01L 21/265; H01L 21/225; H01L 29/66

(52) U.S. Cl. CPC H01L 29/7813; H01L 29/063; H01L 29/1095; H01L 29/66734; H01L 29/42364; H01L 21/26513; H01L 21/2253; H01L 29/4236

(57) ABSTRACT

A metal oxide semiconductor field effect transistor and a method for manufacturing the same are provided. The metal oxide semiconductor field effect transistor includes a substrate structure, doped regions, trench oxide layers, semiconductor layer structures, a dielectric layer structure and a metal structure. The substrate structure includes a base layer and an epitaxial layer having a plurality of trenches. A trench depth of each trench is X1 micrometer. The doped regions are respectively formed at bottoms of the trenches. The trench oxide layers are respectively formed on inner walls of the trenches. An oxide layer thickness of each trench oxide layer is X2 micrometers. X1 and X2 conform to the following relationship: 0.05X1≤X2≤0.25X1. The semiconductor layer structures are respectively formed in the trenches. The dielectric layer structure is formed on the semiconductor layer structures. The metal structure is formed on the dielectric layer structure.

### FIELD OF THE DISCLOSURE

The present disclosure relates to a metal oxide semiconductor field effect transistor, in particular to a metal oxide semiconductor field effect transistor suitable for power supply and a method for manufacturing the same.

### BACKGROUND OF THE DISCLOSURE

With the advancement of electronic technology and the trend of miniaturization of electronic products, increasingly more electronic components are produced by integrated circuit manufacturing process. However, many aspects need to be considered for integrated circuit type electronic components, such as issues of high voltage resistance, mutual interference or anti-noise, especially when being used in power supplies. Since the power supply needs to receive a high voltage input, and the high voltage may cause the integrated circuit type electronic components to burn out, therefore causing the power supply to malfunction, which is the main reason that the size of the power supply cannot be reduced in the application of integrated circuit type electronic components.

Metal oxide semiconductor field effect transistors are also commonly used in power supplies. Since the operation speed of the metal oxide semiconductor field effect transistors is quite fast and the voltage signal processing performance thereof is outstanding, the metal oxide semiconductor field effect transistors can be applied as power converters. In response to the miniaturization trend of the electronic products, the metal oxide semiconductor field effect transistors have also gradually moved towards integrated circuitization. However, when the power supply receives a high voltage input, the integrated circuit type metal oxide semiconductor field effect transistors may be unable to withstand the high voltage and burn out.

### SUMMARY OF THE DISCLOSURE

In response to the above-referenced technical inadequacies, the present disclosure provides a metal oxide semiconductor field effect transistor and a method for manufacturing the same.

In one aspect, the present disclosure provides a metal oxide semiconductor field effect transistor which includes a substrate structure, a plurality of doped regions, a plurality of trench oxide layers, a plurality of semiconductor layer structures, a dielectric layer structure, and a metal structure. The substrate structure includes a base layer and an epitaxial layer. The epitaxial layer is formed on the base layer, and the epitaxial layer has a plurality of trenches which are respectively recessed from a surface of the epitaxial layer away from the base layer and arranged at intervals from each other; in which a trench depth of each of the trenches is X1 micrometers, and X1 is a real number greater than zero. The plurality of doped regions are respectively formed at bottoms of the plurality of trenches and diffuse toward a portion of the epitaxial layer. The plurality of trench oxide layers are respectively formed on inner walls of the plurality of trenches, in which bottoms of the plurality of trench oxide layers respectively abut on the plurality of doped regions, and each of the trench oxide layers surrounds a groove; in which an oxide layer thickness of each of the trench oxide layers is X2 micrometers, and X2 is a real number greater than zero. In each of the trenches and the corresponding trench oxide layer, X1 and X2 conform to the following relationship: 0.05X1≤X2≤0.25X1. The plurality of semiconductor layer structures are respectively formed and filled in the plurality of grooves, so as to form a plurality of trench-type structures together with the plurality of trench oxide layers. The dielectric layer structure is formed and covered on the plurality of semiconductor layer structures and located above the epitaxial layer. The metal structure is formed on a surface of the dielectric layer structure away from the base layer, and the metal structure is electrically connected to at least one trench-type structure of the plurality of trench-type structures. The metal oxide semiconductor field effect transistor is suitable for receiving a working voltage between 50 volts and 800 volts to pass therethrough.

In another aspect, the present disclosure provides a method for manufacturing a metal oxide semiconductor field effect transistor, which includes: providing a substrate structure which includes a base layer and an epitaxial layer formed on the base layer; forming a plurality of trenches recessed in the epitaxial layer, respectively, according to a preset trench depth, in which the plurality of trenches are respectively recessed from a surface of the epitaxial layer away from the base layer and arranged at intervals from each other, the preset trench depth is defined as X1 micrometers, and X1 is a real number greater than zero; forming a plurality of doped regions at bottoms of the plurality of trenches, respectively, in which the plurality of doped regions are respectively diffused from the bottoms of the plurality of trenches toward a portion of the epitaxial layer; forming a plurality of trench oxide layers on inner walls of the plurality of trenches, respectively, according to a preset oxide layer thickness, in which bottoms of the plurality of trench oxide layers respectively abut on the plurality of doped regions, and each of the trench oxide layers surrounds a groove, in which the preset oxide layer thickness is defined as X2 micrometers, and X2 is a real number greater than zero; in which X1 and X2 conform to the following relationship: 0.05X1≤X2≤0.25X1; forming a plurality of semiconductor layer structures in the plurality of grooves, respectively, so that the plurality of semiconductor layer structures and the plurality of trench oxide layers together form a plurality of trench-type structures, respectively; forming a dielectric layer structure on the plurality of semiconductor layer structures such that the dielectric layer structure covers the plurality of semiconductor layer structures, and the dielectric layer structure is located above the epitaxial layer; and forming a metal structure on a surface of the dielectric layer structure away from the base layer to form the metal oxide semiconductor field effect transistor, in which the metal structure is electrically connected to at least one trench-type structure of the plurality of trench-type structures.

Therefore, an advantage of the present disclosure is that the technical features of “a trench depth of each of the trenches is X1 micrometers, and X1 is a real number greater than zero” and “an oxide layer thickness of each of the trench oxide layers is X2 micrometers, and X2 is a real number greater than zero; in which in each of the trenches and the corresponding trench oxide layer, X1 and X2 conform to the following relationship: 0.05X1≤X2≤0.25X1” can enable the finally produced metal oxide semiconductor field effect transistor to withstand a higher working voltage without burnout, thereby improving the reliability of the device.

Further, another advantage of the present disclosure is that the method for manufacturing the metal oxide semiconductor field effect transistor can adjust the trench depth of the trench and correspondingly adjust the thickness of the trench oxide layer, so that the finally produced metal oxide semiconductor field effect transistor can be adapted to different operating voltage specifications.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a cross-sectional view of a metal oxide semiconductor field effect transistor according to an embodiment of the present disclosure.

FIG. 2A is a schematic view of step S110 of a method for manufacturing the metal oxide semiconductor field effect transistor according to the embodiment of the present disclosure.

FIG. 2B is a schematic view of step S120 of the method for manufacturing the metal oxide semiconductor field effect transistor according to the embodiment of the present disclosure.

FIG. 2C is a schematic view of step S130 of the method for manufacturing the metal oxide semiconductor field effect transistor according to the embodiment of the present disclosure.

FIG. 2D is a schematic view of step S140 of the method for manufacturing the metal oxide semiconductor field effect transistor according to the embodiment of the present disclosure.

FIG. 2E is a schematic view of step S150 of the method for manufacturing the metal oxide semiconductor field effect transistor according to the embodiment of the present disclosure.

FIG. 2F is a schematic view of step S160 of the method for manufacturing the metal oxide semiconductor field effect transistor according to the embodiment of the present disclosure.

FIG. 2G is a schematic view of step S170 of the method for manufacturing the metal oxide semiconductor field effect transistor according to the embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### Method for Manufacturing MOSFET

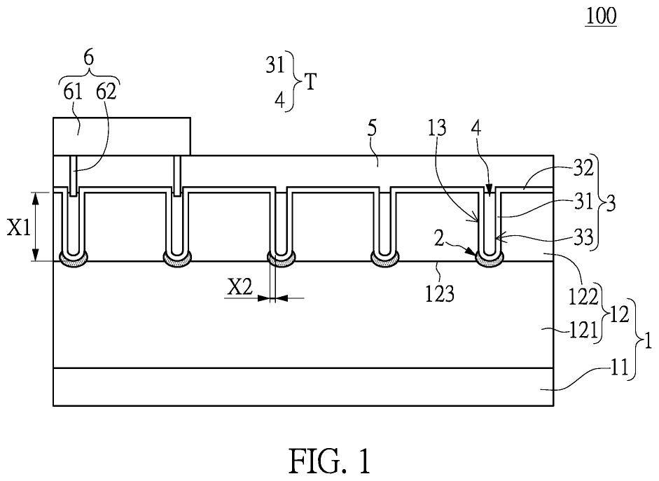

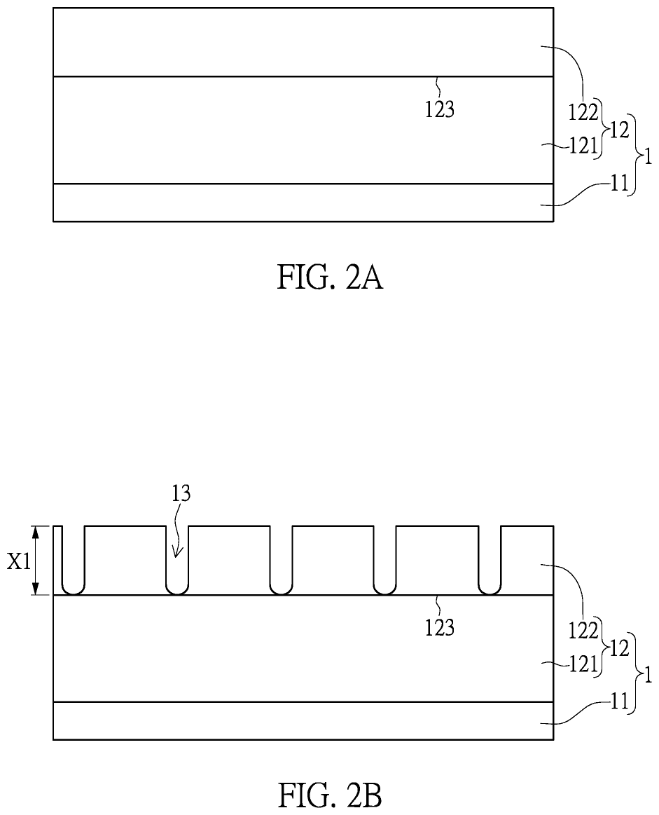

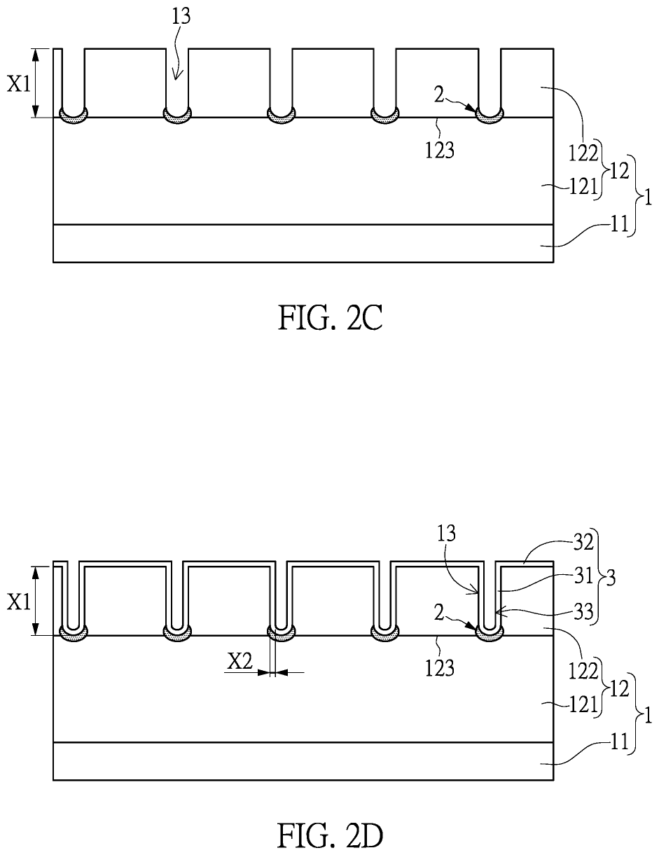

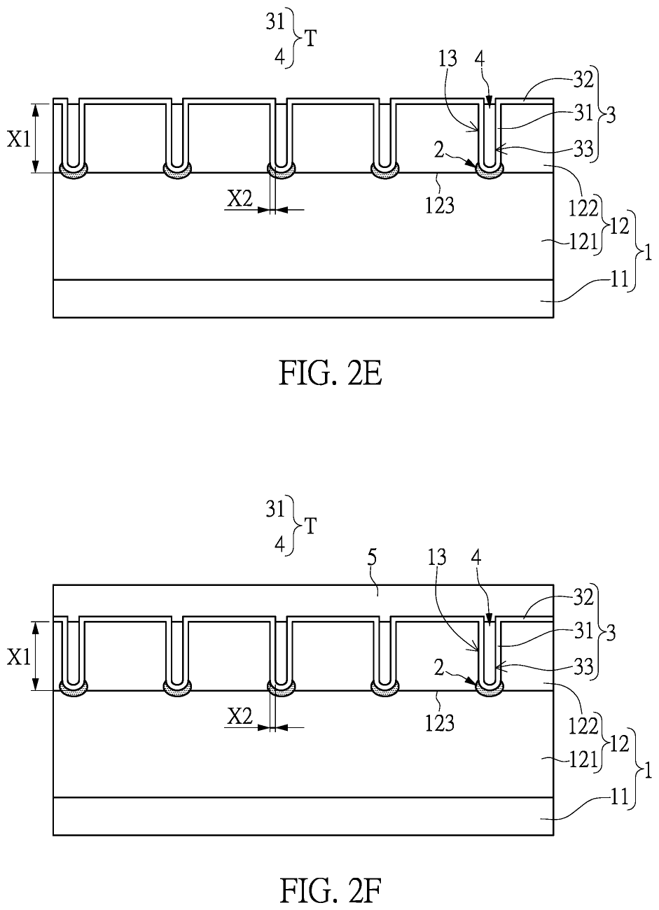

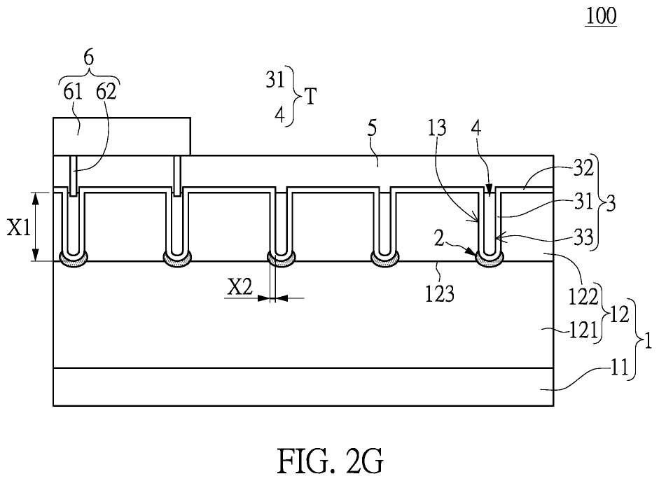

Referring to FIG. 1 and FIG. 2A to FIG. 2G, an embodiment of the present disclosure provides a method for manufacturing a metal oxide semiconductor field effect transistor (abbreviated as MOSFET), which includes steps S110 to S170. In the present embodiment, the metal oxide semiconductor field effect transistor is a power element, such as a power supply or a transformer, but the present disclosure is not limited thereto. It should be noted that the order of the steps and the actual way of operation in the present embodiment can be adjusted according to requirements, and are not limited to those in the present embodiment.

In the present embodiment, the method for manufacturing the metal oxide semiconductor field effect transistor is firstly described below. For ease of understanding, a unit region of the metal oxide semiconductor field effect transistor is taken as an example, and a cross-sectional view of the unit region is used for explanation. The diagram corresponding to each step can be referred to, as can be referred to the diagrams of other steps, if necessary. The specific steps of the method for manufacturing the metal oxide semiconductor field effect transistor are described below.

Referring to FIG. 2A, the step S110 includes: providing a substrate structure 1. The substrate structure 1 includes a base layer 11 and an epitaxial layer 12 formed on the base layer 11, in which two opposite surfaces of the substrate structure 1 are respectively defined as a top surface and a bottom surface (not labeled in the drawings). More specifically, the surface of the epitaxial layer 12 away from the base layer 11 is defined as the top surface, and the surface of the base layer 11 away from the epitaxial layer 12 is defined as the bottom surface.

Further, a material of the base layer 11 may be, for example, an N-type doped semiconductor or a P-type doped semiconductor. The epitaxial layer 12 may be formed on the base layer 11 by an epitaxial process, and a conductive type of the epitaxial layer 12 may be the same as a conductive type of the base layer 11 (i.e. N-type doping or P-type doping). In the present embodiment, the base layer 11 is an N-type doped semiconductor, and the epitaxial layer 12 is also an N-type doped semiconductor. In addition, a doping concentration of the base layer 11 is greater than that of the epitaxial layer 12, but the present disclosure is not limited thereto.

Further referring to FIG. 2A, in the present embodiment, the epitaxial layer 12 further includes a first epitaxial layer 121 and a second epitaxial layer 122. Firstly, the first epitaxial layer 121 is formed on the base layer 11 by the epitaxial process, and then the second epitaxial layer 122 is formed on the first epitaxial layer 121 by the epitaxial process. Accordingly, the first epitaxial layer 121 is located between the base layer 11 and the second epitaxial layer 122, and the first epitaxial layer 121 and the second epitaxial layer 122 has an interface 123 formed therebetween.

The conductive type of the base layer 11 is the same as the conductive type of the first epitaxial layer 121, and is also the same as the conductive type of the second epitaxial layer 122. That is, in the present embodiment, the conductive types of the base layer 11, the first epitaxial layer 121, and the second epitaxial layer 122 are all N-type doping, but the present disclosure is not limited thereto.

The doping concentration of the base layer 11 is greater than that of the first epitaxial layer 121, and is also greater than that of the second epitaxial layer 122.

In an embodiment of the present disclosure, the doping concentration of the base layer 11 is approximately between 10¹⁸/cm³ and 10¹⁹/cm³, the doping concentration of the first epitaxial layer 121 is approximately between 10¹⁴/cm³ and 10¹⁶/cm³, and the doping concentration of the second epitaxial layer 122 is also approximately between 10¹⁴/cm³ and 10¹⁶/cm³. Furthermore, the doping concentration of the first epitaxial layer 121 is different from the doping concentration of the second epitaxial layer 122, and the doping concentration of each of the first epitaxial layer 121 and the second epitaxial layer 122 is uniformly distributed.

Referring to FIG. 2B, the step S120 includes: forming a plurality of trenches 13 recessed in the epitaxial layer 12, respectively, according to a preset trench depth. The plurality of trenches 13 may be formed by, for example, etching, but the present disclosure is not limited thereto.

In addition, the plurality of trenches 13 are respectively recessed from a surface of the epitaxial layer 12 away from the base layer 11 and arranged at intervals from each other. The preset trench depth is defined as X1 micrometers, and X1 is a real number greater than zero. In the present embodiment, X1 is a real number that is not less than 4 and not greater than 16.

Accordingly, each of the trenches 13 has a trench depth of X1 micrometer.

Further, the bottoms of the plurality of trenches 13 are not in contact with the base layer 11 and are spaced apart from the base layer 11 by a distance. In other words, the plurality of trenches 13 are recessed from the top surface of the base structure 1 and not in contact with the base layer 11 of the base structure 1.

More specifically, the first epitaxial layer 121 and the second epitaxial layer 122 have an interface 123 formed therebetween. The interface 123 is substantially located at (or aligned with) the bottoms of the plurality of trenches 13, and the interface 123 is extendingly connected between a plurality of doped regions 2 as shown in FIG. 2C. The plurality of trenches 13 are respectively recessed from a surface of the second epitaxial layer 122 away from the first epitaxial layer 121, the plurality of trenches 13 are substantially located in the second epitaxial layer 122, and the plurality of trenches 13 are located above the first epitaxial layer 121. In addition, the plurality of trenches 13 are not in contact with or only partially overlap the first epitaxial layer 121, but the present disclosure is not limited thereto. It is worth mentioning that in the present embodiment, although the interface 123 is aligned with the bottoms of the plurality of trenches 13 as an example for description, the present disclosure is not limited thereto. For example, the interface 123 may be adjacently disposed below the bottoms of the plurality of trenches 13 and spaced a short distance apart from the bottoms of the plurality of trenches 13.

It should be noted that FIG. 2B is described by using an example in which the trench depths X1 of the plurality of trenches 13 are the same with each other, but the present disclosure is not limited thereto. For example, in an embodiment not shown in the present disclosure, the trench depths X1 of the plurality of trenches 13 may be different from each other.

In addition, it should be noted that the plurality of trenches 13 are described with respect to the trenches 13 at different locations in the epitaxial layer 12 from a sectional view angle. When viewing the MOSFET as a whole, the trenches 13 may be in communication with each other or be separate from each other, and the present disclosure is not limited thereto.

Referring to FIG. 2C, the step S130 includes: forming a plurality of doped regions 2 at the bottoms of the plurality of trenches 13, respectively. The plurality of doped regions 2 are respectively diffused from the bottoms of the plurality of trenches 13 toward a portion of the epitaxial layer 12. The plurality of doped regions 2 may be formed by an ion implantation process, but the present disclosure is not limited thereto.

That is, the bottom of each of the trenches 13 is formed with a doped region 2. Each of the doped regions 2 diffuses from the bottom of the corresponding trench 13 toward a portion of the epitaxial layer 12. Accordingly, each of the doped regions 2 surrounds the periphery of the bottom of the corresponding trench 13. In addition, in the present embodiment, each of the doped regions 2 only slightly diffuses from the bottom of the corresponding trench 13 toward the epitaxial layer 12 and is presented as a half-moon structure. Each of the doped regions 2 is not in contact with the base layer 11 and is spaced apart from the base layer 11 by a distance. It is worth mentioning that, in the present embodiment, each of the doped regions 2 is partially located in the first epitaxial layer 121 and partially located in the second epitaxial layer 122.

Furthermore, in the present embodiment, the conductive types of the plurality of doped regions 2 are different from the conductive types of the base layer 11 and the epitaxial layer 12. That is, the plurality of doped regions 2 in the present embodiment are P-type doped semiconductors. The implanted ion type of the doped regions 2 may be, for example, boron ions (B+).

In addition, it is worth mentioning that the plurality of doped regions 2 (P-type doped semiconductors) and the epitaxial layer 12 (N-type doped semiconductor) can be formed together as a P-N junction diode.

In an embodiment of the present disclosure, a doping concentration of each of the doped regions 2 is approximately between 10¹⁵/cm³ and 10¹⁷/cm³.

It is worth mentioning that the doping concentrations of the first epitaxial layer 121, the second epitaxial layer 122, and the plurality of doped regions 2 need to be low doping concentrations (i.e. not greater than 10¹⁷/cm³) to reduce the conductivity of the components. Accordingly, the finally produced metal oxide semiconductor field effect transistor 100 can withstand a higher operating voltage. If the doping concentrations of the first epitaxial layer 121, the second epitaxial layer 122, and the plurality of doped regions 2 are high doping concentrations (i.e. greater than 10¹⁸/cm³), the finally produced metal oxide semiconductor field effect transistor 100 may be burned out due to excessive working voltage.

Referring to FIG. 2D, the step S140 includes: extendingly forming an oxide layer structure 3 on the surface of the epitaxial layer 12 away from the base layer 11 and the inner walls of the plurality of trenches 13 according to a preset oxide layer thickness. The oxide layer structure 3 may be formed by a low temperature oxide deposition (LTO deposition) process, but the present disclosure is not limited thereto.

More specifically, the oxide layer structure 3 includes a plurality of trench oxide layers 31 and a cover oxide layer 32. The plurality of trench oxide layers 31 are respectively formed on the inner walls of the plurality of trenches 13, and the bottoms of the plurality of trench oxide layers 31 respectively abut on the plurality of doped regions 2. Each of the trench oxide layers 31 surrounds a groove 33. Furthermore, the cover oxide layer 32 is formed on the surface of the epitaxial layer 12 away from the base layer 11 (i.e. the top surface of the epitaxial layer 12), and the cover oxide layer 32 is extendingly connected between the plurality of trench oxide layers 31. In addition, the material of the oxide layer structure 3 may be made of, for example, a silicon compound or other dielectric materials. For example, the aforementioned silicon compound may be, for example, silicon dioxide or silicate, and is preferably silicon dioxide, but the present disclosure is not limited thereto.

The preset oxide layer thickness is defined as X2 micrometers, and X2 is a real number greater than zero. In the present embodiment, X2 is a real number that is not less than 0.5 and not greater than 1.5, but the present disclosure is not limited thereto. Accordingly, each of the trench oxide layers 31 has an oxide layer thickness of X2 micrometers.

Furthermore, the preset trench depth X1 and the preset oxide layer thickness X2 conform to the following relationship: 0.05X1≤X2≤0.25X1.

According to the above configuration, since the trench depth X1 of each of the trenches 13 is between 4 micrometers and 16 micrometers, the oxide layer thickness X2 of each of the trench oxide layers 31 is between 0.5 micrometers (5 kÅ) and 1.5 micrometers (15 kÅ), and the material of each of the trench oxide layers 31 is silicon dioxide or silicate with high resistance and low conductivity, the finally produced metal oxide semiconductor field effect transistor 100 of the present embodiment is suitable for receiving a working voltage between 50 volts and 800 volts to pass therethrough, and the working voltage is preferably between 200 volts and 700 volts.

It is worth mentioning that the method for manufacturing the metal oxide semiconductor field effect transistor of the present embodiment can adjust a value range of the preset trench depth X1 according to a predetermined working voltage, and can adjust a value range of the preset oxide layer thickness X2 according to the value range of the preset trench depth X1. Accordingly, the finally produced metal oxide semiconductor field effect transistor 100 will not be burned out due to an excessively high voltage, and the reliability of the finally produced metal oxide semiconductor field effect transistor 100 can be improved.

More specifically, in the present embodiment, the value range of the preset trench depth X1 and the value range of the preset oxide layer thickness X2 meet only one of the following conditions:

i) if the preset trench depth X1 is between 4 micrometers and 7 micrometers, the preset oxide layer thickness X2 is between 0.5 micrometers (5 kÅ) and 0.9 micrometers (9 kÅ), and X1 and X2 conform to the following relationship: 0.071X1≤X2≤0.225X1, so that the finally produced metal oxide semiconductor field effect transistor 100 is suitable for receiving a working voltage between 75 volts and 275 volts to pass therethrough, and the working voltage is preferably between 100 volts and 250 volts.

ii) if the preset trench depth X1 is between 7 micrometers and 16 micrometers, the preset oxide layer thickness X2 is between 1.2 micrometers (12 kÅ) and 1.5 micrometers (15 kÅ), and X1 and X2 conform to the following relationship: 0.075X1≤X2≤0.220X1, so that the finally produced metal oxide semiconductor field effect transistor 100 is suitable for receiving a working voltage between 275 volts and 800 volts to pass therethrough, and the working voltage is preferably between 300 volts and 700 volts.

If the value range of the preset trench depth X1 and the value range of the preset oxide layer thickness X2 do not meet one of the above conditions, the finally produced metal oxide semiconductor field effect transistor 100 will not be suitable for receiving the corresponding working voltage to pass therethrough, which may cause burnout or poor reliability. For example, if the oxide layer thickness X2 of the trench oxide layer 31 is too thin, the finally produced metal oxide semiconductor field effect transistor 100 will not be able to withstand a high voltage due to the reduced resistance value, and the transistor 100 may be burned out.

Referring to FIG. 2E, which is to be read in conjunction with FIG. 1, the step S150 includes: respectively forming a plurality of semiconductor layer structures 4 in the plurality of grooves 33 that are surrounded by the plurality of trench oxide layers 31, so that the plurality of semiconductor layer structures 4 and the plurality of trench oxide layers 31 together form a plurality of trench-type structures T.

Further, the plurality of semiconductor layer structures 4 are respectively filled in the grooves 33 that are surrounded by the plurality of trench oxide layers 31. The plurality of semiconductor layer structures 4 may be subjected to an etch-back step, so that a height of the exposed outer surfaces of the semiconductor layer structures 4 (i.e. the top surfaces of the semiconductor layer structures 4 in FIG. 2E) are lower than a height of the outer surface of the cover oxide layer 32 (i.e. the surface of the cover oxide layer 32 away from the epitaxial layer 12 in FIG. 2E), but the present disclosure is not limited thereto. The exposed outer surfaces of the semiconductor layer structures 4 are substantially aligned with the top surface of the second epitaxial layer 122. Moreover, the material of the plurality of semiconductor layer structures 4 may be, for example, doped poly-silicon.

It is worth mentioning that, in an embodiment of the present disclosure, the plurality of trenches 13 may be defined as deep trenches. The epitaxial layer 12 may further have a plurality of shallow trenches (not shown) formed between the plurality of deep trenches 13. Moreover, the trench depths of the plurality of shallow trenches are all smaller than the trench depths of the plurality of deep trenches. The plurality of shallow trenches may be used to form a plurality of trench-type gate structures, and the plurality of deep trenches may be used to form a plurality of trench-type source structures. In addition, a drain wire can be connected below the substrate structure 1, but the present disclosure is not limited thereto.

Referring to FIG. 2F, the step S160 includes: forming and covering a dielectric layer structure 5 (interlayer dielectric, ILD) on the oxide layer structure 3 and the plurality of semiconductor layer structures 4, so that the oxide layer structure 3 and the plurality of semiconductor layer structures 4 are embedded in the dielectric layer structure 5. The dielectric layer structure 5 may be formed by, for example, a chemical vapor deposition method, but the present disclosure is not limited thereto. The dielectric layer structure 5 may also be formed by, for example, a physical vapor deposition method or other suitable deposition processes. Furthermore, the material of the dielectric layer structure 5 may be made of, for example, a silicon compound or other dielectric materials.

In addition, the outer surface of the dielectric layer structure 5 may be planarized by a chemical mechanical polishing (CMP) process, but the present disclosure is not limited thereto.

Referring to FIG. 2G, which is to be read in conjunction with FIG. 1, the step S170 includes: forming a metal structure 6 on a surface of the dielectric layer structure 5 away from the base layer 11 to form the metal oxide semiconductor field effect transistor 100. The metal structure 6 partially penetrates through the dielectric layer structure 5 and is electrically connected to at least one of the plurality of trench-type structures T. The metal structure 6 may be formed, for example, by a deposition method, and in the present embodiment, the metal structure 6 is an integrated structure formed of an aluminum-silicon-copper alloy. However, in practical applications, the present disclosure is not limited thereto.

Further, the metal structure 6 includes a conductive portion 61 and two contact plugs 62 integrally formed with the conductive portion 61. The conductive portion 61 is formed on a surface of the dielectric layer structure 5 away from the base layer 11. The two contact plugs 62 are disposed at a distance from each other. The two contact plugs 62 respectively penetrate through the dielectric layer structure 5. Accordingly, the conductive portion 61 can be electrically connected to two adjacent trench-type structures T of the plurality of trench-type structures T through the two contact plugs 62, respectively. In addition, a width of each of the contact plugs 62 is less than a width of the corresponding trench-type structure T and a width of the corresponding trench 13.

More specifically, the two contact plugs 62 are respectively formed through the dielectric layer structure 5, and the two contact plugs 62 partially extend into the semiconductor layer structures 4 of the two adjacent trench-type structures T, respectively. Accordingly, the conductive portion 61 can be electrically connected to the semiconductor layer structures 4 of the two adjacent trench-type structures T through the two contact plugs 62 (as shown in FIG. 1), so that the semiconductor layer structures 4 of the two adjacent trench-type structures T are equipotential compared to the two contact plugs 62 to which they are electrically connected.

Furthermore, in the present embodiment, the conductive portion 61 covers only a part of the outer surface of the dielectric layer structure 5 and the other part of the outer surface of the dielectric layer structure 5 is exposed to the outside.

It is worth mentioning that before the metal structure 6 is formed, the manufacturing method of the present embodiment further includes: forming two contact grooves (not labeled in the drawings) recessed in the dielectric layer structure 5 by means of etching to provide the two aforementioned contact plugs 62 to be respectively formed therein.

After implementing the above steps S110 to S170, the metal oxide semiconductor field effect transistor 100 (also referred to as a trench-type power element) shown in FIG. 1 can be completed, but in practical applications, each step may be substituted with a reasonable variation. Furthermore, it should be noted that the above steps are described from the perspective of a sectional view. Under the premise that conditions in the above steps are met, the possibility of implementing the present disclosure in various design layouts is not excluded. In other words, if viewed from a top view, the metal oxide semiconductor field effect transistor of the present disclosure may have different design layouts.

Furthermore, it is worth mentioning that the above-mentioned metal structure 6 partially penetrates the dielectric layer structure 5 to be in direct contact and electrically connected to at least one of the plurality of trench-type structures T, but the present disclosure is not limited thereto. For example, the metal structure 6 may not penetrate through the dielectric layer structure 5, and may be electrically connected to at least one of the plurality of trench-type structures T via an external wire. Accordingly, the above-mentioned metal structure 6 may not directly contact any of the trench-type structures T.

### Metal Oxide Semiconductor Field Effect Transistor

The method for manufacturing the metal oxide semiconductor field effect transistor according to the embodiment of the present disclosure has been described above. The specific structure of the metal oxide semiconductor field effect transistor 100 of the present embodiment will be described below. It should be noted that although the metal oxide semiconductor field effect transistor 100 of the present embodiment is manufactured by the above-mentioned manufacturing method, the present disclosure is not limited thereto. That is, the metal oxide semiconductor field effect transistor of the present disclosure may be produced by other methods for manufacturing the transistor.

As shown in FIG. 1, the present embodiment further discloses a metal oxide semiconductor field effect transistor 100, which includes a substrate structure 1, a plurality of doped regions 2, an oxide layer structure 3, a plurality of semiconductor layer structures 4, a dielectric layer structure 5 and a metal structure 6.

The substrate structure 1 includes a base layer 11 and an epitaxial layer 12. The epitaxial layer 12 is formed on the base layer 11. The epitaxial layer 12 has a plurality of trenches 13, and the plurality of trenches 13 are respectively recessed from a surface of the epitaxial layer 12 away from the base layer 11 and arranged at intervals from each other, in which a trench depth of each of the trenches is X1 micrometers, and X1 is a real number greater than zero.

The plurality of doped regions 2 are respectively formed at bottoms of the plurality of trenches 13, and the plurality of doped regions 2 diffuse toward a portion of the epitaxial layer 12.

The oxide layer structure 3 includes a plurality of trench oxide layers 31 and a cover oxide layer 32. The plurality of trench oxide layers 31 are respectively formed on the inner walls of the plurality of trenches 13, and the bottoms of the plurality of trench oxide layers 31 respectively abut on the plurality of doped regions 2. Each of the trench oxide layers 31 surrounds a groove 33. Furthermore, the cover oxide layer 32 is formed on the surface of the epitaxial layer 12 away from the base layer 11, and the cover oxide layer 32 is extendingly connected between the plurality of trench oxide layers 31. Each of the trench oxide layers 31 has an oxide layer thickness of X2 micrometers, and X2 is a real number greater than zero. In each of the trenches 13 and the corresponding trench oxide layer 31, X1 and X2 conform to the following relationship: 0.05X1≤X2≤0.25X1.

The plurality of semiconductor layer structures 4 are respectively formed and filled in the plurality of grooves 33, and the plurality of semiconductor layer structures 4 and the plurality of trench oxide layers 31 together form a plurality of trench-type structures T.

The dielectric layer structure 5 is formed and covered on the oxide layer structure 3 and the plurality of semiconductor layer structures 4.

The metal structure 6 is formed on a surface of the dielectric layer structure 5 away from the base layer 11. The metal structure 6 partially penetrates through the dielectric layer structure 5, so that the metal structure 6 is electrically connected to at least one of the plurality of trench-type structures T, but the present disclosure is not limited thereto. For example, the metal structure 6 may not penetrate through the dielectric layer structure 5, and may be electrically connected to at least one of the plurality of trench-type structures T via an external wire.

According to the above configuration, the metal oxide semiconductor field effect transistor 100 of the present embodiment is suitable for receiving a working voltage between 50 volts and 800 volts to pass therethrough, and the working voltage is preferably between 200 volts and 700 volts.

It is worth mentioning that the metal oxide semiconductor field effect transistor of the present embodiment has a suitable trench depth X1 according to a required working voltage, and has a suitable oxide layer thickness X2 according to the trench depth X1. Accordingly, the metal oxide semiconductor field effect transistor 100 is suitable for the required working voltage, and the metal oxide semiconductor field effect transistor 100 will not be burned out due to an excessively high voltage.

In an embodiment of the present disclosure, the trench depth X1 of the trench 13 is between 4 micrometers and 6 micrometers, the oxide layer thickness X2 of the trench oxide layer is between 0.5 micrometers and 0.6 micrometers, and X1 and X2 conform to the following relationship: 0.08 X1≤X2≤0.15X1.

Accordingly, the metal oxide semiconductor field effect transistor 100 is suitable for receiving the working voltage between 75 volts and 125 volts to pass therethrough.

In an embodiment of the present disclosure, the trench depth X1 of the trench 13 is between 5 micrometers and 7 micrometers, the oxide layer thickness X2 of the trench oxide layer is between 0.7 micrometers and 0.9 micrometers, and X1 and X2 conform to the following relationship: 0.10X1≤X2≤0.18X1.

Accordingly, the metal oxide semiconductor field effect transistor 100 is suitable for receiving the working voltage between 125 volts and 275 volts to pass therethrough.

In an embodiment of the present disclosure, the trench depth X1 of the trench 13 is between 7 micrometers and 16 micrometers, the oxide layer thickness X2 of the trench oxide layer is between 1.2 micrometers and 1.5 micrometers, and X1 and X2 conform to the following relationship: 0.075X1≤X2≤0.220X1.

Accordingly, the metal oxide semiconductor field effect transistor 100 is suitable for receiving the working voltage between 275 volts and 800 volts to pass therethrough.

It is worth mentioning that, as described in the above embodiment, the number of the plurality of trenches 13 is five, and the number of the plurality of trench-type structures T is also five, but the present disclosure is not limited thereto. The number of the plurality of trenches 13 and the number of the trench-type structures T can be adjusted according to design requirements.

### ADVANTAGES OF THE EMBODIMENT

In conclusion, an advantage of the present embodiment is that the technical features of “a trench depth of each of the trenches is X1 micrometers, and X1 is a real number greater than zero” and “an oxide layer thickness of each of the trench oxide layers is X2 micrometers, and X2 is a real number greater than zero; in which in each of the trenches and the corresponding trench oxide layer, X1 and X2 conform to the following relationship: 0.05X1≤X2≤0.25X1” can enable the finally produced metal oxide semiconductor field effect transistor to withstand a higher working voltage without burnout, thereby improving the reliability of the device.

Further, another advantage of the present embodiment is that the method for manufacturing the metal oxide semiconductor field effect transistor can adjust the trench depth of the trench and correspondingly adjust the thickness of the trench oxide layer, so that the finally produced metal oxide semiconductor field effect transistor can be adapted to different operating voltage specifications.

In addition, in terms of wafer design, since the metal oxide semiconductor field effect transistor of the present embodiment can withstand a higher operating voltage without the need to connect other metal oxide semiconductor field effect transistor in series, the area occupied by the metal oxide semiconductor field effect transistor on the wafer can be greatly reduced, and other electronic components can be designed on the wafer to diversify the functions provided by the wafer.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A metal oxide semiconductor field effect transistor, comprising:
a substrate structure including;
a base layer; and
an epitaxial layer formed on the base layer, and the epitaxial layer having a plurality of trenches which are respectively recessed from a surface of the epitaxial layer away from the base layer and arranged at intervals from each other; wherein a trench depth of each of the trenches is X1 micrometers, and X1 is a real number greater than zero;
a plurality of doped regions respectively formed at bottoms of the plurality of trenches and diffusing toward a portion of the epitaxial layer;
a plurality of trench oxide layers respectively formed on inner walls of the plurality of trenches; wherein bottoms of the plurality of trench oxide layers respectively abut on the plurality of doped regions, and each of the trench oxide layers surrounds a groove; wherein an oxide layer thickness of each of the trench oxide layers is X2 micrometers, and X2 is a real number greater than zero; wherein in each of the trenches and the corresponding trench oxide layer, X1 and X2 conform to the following relationship: 0.05X1≤X2≤0.25X1;
a plurality of semiconductor layer structures respectively formed and filled in the plurality of grooves, so as to form a plurality of trench-type structures together with the plurality of trench oxide layers;
a dielectric layer structure formed and covered on the plurality of semiconductor layer structures and located above the epitaxial layer; and
a metal structure formed on a surface of the dielectric layer structure away from the base layer; wherein the metal structure is electrically connected to at least one trench-type structure of the plurality of trench-type structures;
wherein the metal oxide semiconductor field effect transistor is suitable for receiving a working voltage between 50 volts and 800 volts to pass therethrough.

2. The metal oxide semiconductor field effect transistor according to claim 1, wherein in each of the trenches and the corresponding trench oxide layer, the trench depth X1 of the trench is between 4 micrometers and 7 micrometers, the oxide layer thickness X2 of the trench oxide layer is between 0.5 micrometers and 0.9 micrometers, and X1 and X2 conform to the following relationship: 0.071X1≤X2≤0.225X1.

3. The metal oxide semiconductor field effect transistor according to claim 2, wherein the metal oxide semiconductor field effect transistor is suitable for receiving the working voltage between 75 volts and 275 volts to pass therethrough.

4. The metal oxide semiconductor field effect transistor according to claim 1, wherein in each of the trenches and the corresponding trench oxide layer, the trench depth X1 of the trench is between 7 micrometers and 16 micrometers, the oxide layer thickness X2 of the trench oxide layer is between 1.2 micrometers and 1.5 micrometers, and X1 and X2 conform to the following relationship: 0.075X1≤X2≤0.220X1.

5. The metal oxide semiconductor field effect transistor according to claim 4, wherein the metal oxide semiconductor field effect transistor is suitable for receiving the working voltage between 275 volts and 800 volts to pass therethrough.

6. The metal oxide semiconductor field effect transistor according to claim 1, wherein the epitaxial layer further includes a first epitaxial layer and a second epitaxial layer, the first epitaxial layer is formed on the base layer, and the second epitaxial layer is formed on the first epitaxial layer such that the first epitaxial layer is located between the base layer and the second epitaxial layer; wherein the first epitaxial layer and the second epitaxial layer have an interface formed therebetween, the interface is located at the bottoms of the plurality of trenches, and the interface is extendingly connected between the plurality of doped regions; wherein the plurality of trenches are respectively recessed from a surface of the second epitaxial layer away from the first epitaxial layer, and the plurality of trenches are located in the second epitaxial layer.

7. The metal oxide semiconductor field effect transistor according to claim 6, wherein a conductive type of the base layer is the same as a conductive type of the first epitaxial layer, and is also the same as a conductive type of the second epitaxial layer; wherein a doping concentration of the base layer is greater than that of the first epitaxial layer, and is also greater than that of the second epitaxial layer; wherein the doping concentration of the first epitaxial layer is different from the doping concentration of the second epitaxial layer.

8. A method for manufacturing a metal oxide semiconductor field effect transistor, comprising:
providing a substrate structure which includes a base layer and an epitaxial layer formed on the base layer;
forming a plurality of trenches recessed in the epitaxial layer, respectively, according to a preset trench depth; wherein the plurality of trenches are respectively recessed from a surface of the epitaxial layer away from the base layer and arranged at intervals from each other; wherein the preset trench depth is defined as X1 micrometers, and X1 is a real number greater than zero;
forming a plurality of doped regions at bottoms of the plurality of trenches, respectively; wherein the plurality of doped regions are respectively diffused from the bottoms of the plurality of trenches toward a portion of the epitaxial layer;
forming a plurality of trench oxide layers on inner walls of the plurality of trenches, respectively, according to a preset oxide layer thickness; wherein bottoms of the plurality of trench oxide layers respectively abut on the plurality of doped regions, and each of the trench oxide layers surrounds a groove; wherein the preset oxide layer thickness is defined as X2 micrometers, and X2 is a real number greater than zero; wherein X1 and X2 conform to the following relationship: 0.05X1≤X2≤0.25X1;
forming a plurality of semiconductor layer structures in the plurality of grooves, respectively, so that the plurality of semiconductor layer structures and the plurality of trench oxide layers together form a plurality of trench-type structures, respectively;
forming a dielectric layer structure on the plurality of semiconductor layer structures such that the dielectric layer structure covers the plurality of semiconductor layer structures, and the dielectric layer structure is located above the epitaxial layer; and
forming a metal structure on a surface of the dielectric layer structure away from the base layer to form the metal oxide semiconductor field effect transistor; wherein the metal structure is electrically connected to at least one trench-type structure of the plurality of trench-type structures.

9. The method for manufacturing the metal oxide semiconductor field effect transistor according to claim 8, wherein the value X2 and the value X1 meet one of the following conditions:
i) if the preset trench depth X1 is between 4 micrometers and 7 micrometers, the preset oxide layer thickness X2 is between 0.5 micrometers and 0.9 micrometers, and X1 and X2 conform to the following relationship: 0.071X1≤X2≤0.225X1, so that the finally produced metal oxide semiconductor field effect transistor is suitable for receiving a working voltage between 75 volts and 275 volts to pass therethrough;
ii) if the preset trench depth X1 is between 7 micrometers and 16 micrometers, the preset oxide layer thickness X2 is between 1.2 micrometers and 1.5 micrometers, and X1 and X2 conform to the following relationship: 0.075X1≤X2≤0.220X1, so that the finally produced metal oxide semiconductor field effect transistor is suitable for receiving a working voltage between 275 volts and 800 volts to pass therethrough.
